(19) United States
(12) Patent Application Publication
(10) Pub. No.: US 2015/0076658 A1
(43) Pub. Date: Mar. 19, 2015

(54) Semiconductor Device Including Capacitor and Method of Manufacturing the Same

(71) Applicants: Wandon KIM, Yongin-si (KR); HyunJeong YANG, Hwaseong-si (KR); Ohseong KWON, Hwaseong-si (KR); Kyuho CHO, Hwaseong-si (KR); Yong-Suk TAK, Seoul (KR)

(72) Inventors: Wandon KIM, Yongin-si (KR); HyunJeong YANG, Hwaseong-si (KR); Ohseong KWON, Hwaseong-si (KR); Kyuho CHO, Hwaseong-si (KR); Yong-Suk TAK, Seoul (KR)

(21) Appl. No.: 14/452,956

(22) Filed: Aug. 6, 2014

(30) Foreign Application Priority Data
Sep. 13, 2013 (KR) 10-2013-0110644

(51) Int. Cl. H01L 49/02

(52) U.S. Cl. CPC H01L 28/65; H01L 28/75
USPC 257/532

(57) ABSTRACT

A semiconductor device includes a lower electrode including at least one of a noble metal and a conductive noble metal oxide, a dielectric layer disposed on the lower electrode and including titanium oxide, a protection insulating layer disposed on the dielectric layer and including tantalum oxide and a barrier oxide, and an upper electrode disposed on the protection insulating layer.

### CROSS-REFERENCE TO RELATED APPLICATION

This U.S. non-provisional patent application claims priority under 35 U.S.C. §119 to Korean Patent Application No. 10-2013-0110644, filed on Sep. 13, 2013, in the Korean Intellectual Property Office, the disclosure of which is hereby incorporated by reference in its entirety.

### BACKGROUND

The inventive concepts relate to semiconductor devices and methods of manufacturing the same, and more particularly, to semiconductor devices including capacitors and methods of manufacturing the same.

Semiconductor devices are widely used in an electronic industry because of their small size, functionality, and/or low manufacturing costs. Semiconductor devices may include various discrete elements, such as, field effect transistors, resistors, memory elements, interconnections and/or capacitors.

A capacitor may be used as a memory element of a semiconductor memory device. A capacitor may also be used in a logic circuit of a semiconductor device. With the development of the electronic industry, semiconductor devices have been increasingly highly integrated. Thus, there has been a trend to reduce the size of capacitors. However, as the size of a capacitor is reduced, its reliability may be diminished.

### SUMMARY

Embodiments of the inventive concepts may provide semiconductor devices including capacitors having high reliability and methods of manufacturing the same.

Embodiments of the inventive concepts may also provide semiconductor devices including capacitors having high capacitance in a limited area and methods of manufacturing the same.

Embodiments of the inventive concepts may further provide highly integrated semiconductor devices and methods of manufacturing the same.

In one aspect, a semiconductor device may include a capacitor. The capacitor may include a lower electrode including at least one of a noble metal and a conductive noble metal oxide, a dielectric layer disposed on the lower electrode, the dielectric layer including titanium oxide, a protection insulating layer disposed on the dielectric layer, the protection insulating layer including tantalum oxide and a barrier oxide, and an upper electrode disposed on the protection insulating layer.

In some embodiments, the barrier oxide may have an energy band gap greater than an energy band gap of the tantalum oxide.

In some embodiments, the energy band gap of the barrier oxide may be equal to or greater than about 5.0 eV.

In some embodiments, the barrier oxide of the protection insulating layer may include a specific element and oxygen. The specific element may include at least one of aluminum, zirconium, and hafnium, and a concentration of the specific element of the barrier oxide may be in a range of about 0.01 at % to about 50 at % in the protection insulating layer.

In some embodiments, the barrier oxide may include at least one of aluminum oxide, zirconium oxide, and hafnium oxide.

In some embodiments, a thickness of the protection insulating layer may be in a range of about 1 Å to about 15 Å.

In some embodiments, the protection insulating layer may be in an amorphous state.

In some embodiments, each of the lower electrode and the dielectric layer may have a rutile crystal structure.

In some embodiments, the dielectric layer may further include an additive oxide, and the additive oxide may have an energy band gap greater than an energy band gap of the titanium oxide.

In some embodiments, the energy band gap of the additive oxide may be equal to or greater than about 5.0 eV.

In some embodiments, the additive oxide may include at least one of aluminum oxide, zirconium oxide, and hafnium oxide.

In some embodiments, the additive oxide may include an additive element and oxygen. The additive element may include at least one of aluminum, zirconium, and hafnium, and a concentration of the additive element of the additive oxide may be in a range of about 0.01 at % to about 30 at % in the dielectric layer.

In some embodiments, the upper electrode may include at least one of a noble metal and a conductive noble metal oxide.

In some embodiments, the upper electrode may have a rutile crystal structure.

In some embodiments, the lower electrode may have a plate-shape, a pillar-shape, or a hollow cylinder-shape.

In some embodiments, the capacitor may include a plurality of capacitors and the plurality of capacitors may include a plurality of lower electrodes. In this case, the semiconductor device may further include a supporting pattern disposed between the lower electrodes. The dielectric layer, the protection insulating layer and the upper electrode may cover surfaces of the plurality of lower electrodes and top and bottom surfaces of the supporting pattern.

In another aspect, a method of manufacturing a semiconductor device may include forming a lower electrode including at least one of a noble metal and a conductive noble metal oxide, forming a dielectric layer including titanium oxide on the lower electrode, forming a protection insulating layer including an insulating oxide on the dielectric layer, forming an upper electrode layer on the protection insulating layer, and patterning the upper electrode layer to form an upper electrode. Reactivity between the insulating oxide of the protection insulating layer and an etching gas used in patterning of the upper electrode layer may be lower than reactivity between the dielectric layer and the etching gas.

In some embodiments, the etching gas may include at least one of argon (Ar), chlorine (Cl₂), and carbon fluoride (CₓF_{y}).

In some embodiments, the insulating oxide of the protection insulating layer may be tantalum oxide.

In some embodiments, the protection insulating layer may further include a barrier oxide, and the barrier oxide may have an energy band gap greater than an energy band gap of the tantalum oxide.

In some embodiments, the protection insulating layer may be formed by at least one of an atomic layer deposition (ALD) process and a chemical vapor deposition (CVD) process.

### BRIEF DESCRIPTION OF THE DRAWINGS

The inventive concepts will become more apparent in view of the attached drawings and accompanying detailed description.

FIG. 1 is a cross-sectional view illustrating a capacitor included in a semiconductor device according to example embodiments of the inventive concepts;

FIG. 2 is a flowchart illustrating a method of manufacturing the capacitor of FIG. 1;

FIG. 3 is a graph illustrating characteristics of a capacitor according to example embodiments of the inventive concepts;

FIG. 4 is a cross-sectional view illustrating a semiconductor device including a capacitor according to some embodiments of the inventive concepts;

FIG. 5 is a cross-sectional view illustrating a semiconductor device including a capacitor according to other embodiments of the inventive concepts;

FIG. 6 is a cross-sectional view illustrating a semiconductor device including a capacitor according to still other embodiments of the inventive concepts;

FIGS. 7 to 12 are cross-sectional views illustrating a method of manufacturing a semiconductor device including a capacitor according to some embodiments of the inventive concepts;

FIGS. 13 to 16 are cross-sectional views illustrating a method of manufacturing a semiconductor device including a capacitor according to other embodiments of the inventive concepts;

FIGS. 17 to 19 are cross-sectional views illustrating a method of manufacturing a semiconductor device including a capacitor according to still other embodiments of the inventive concepts;

FIG. 20 is a schematic block diagram illustrating an example of electronic systems including semiconductor devices according to embodiments of the inventive concepts; and

FIG. 21 is a schematic block diagram illustrating an example of memory cards including semiconductor devices according to embodiments of the inventive concepts.

### DETAILED DESCRIPTION OF THE EMBODIMENTS

The inventive concepts will now be described more fully hereinafter with reference to the accompanying drawings, in which exemplary embodiments of the inventive concepts are shown. The advantages and features of the inventive concepts and methods of achieving them will be apparent from the following exemplary embodiments that will be described in more detail with reference to the accompanying drawings. It should be noted, however, that the inventive concepts are not limited to the following exemplary embodiments, and may be implemented in various forms. Accordingly, the exemplary embodiments are provided only to disclose the inventive concepts and let those skilled in the art know the category of the inventive concepts. In the drawings, embodiments of the inventive concepts are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of oneor more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concepts. Accordingly, shapes of the exemplary views may be modified according to manufacturing techniques and/or allowable errors. Therefore, the embodiments of the inventive concepts are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concepts.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concepts explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

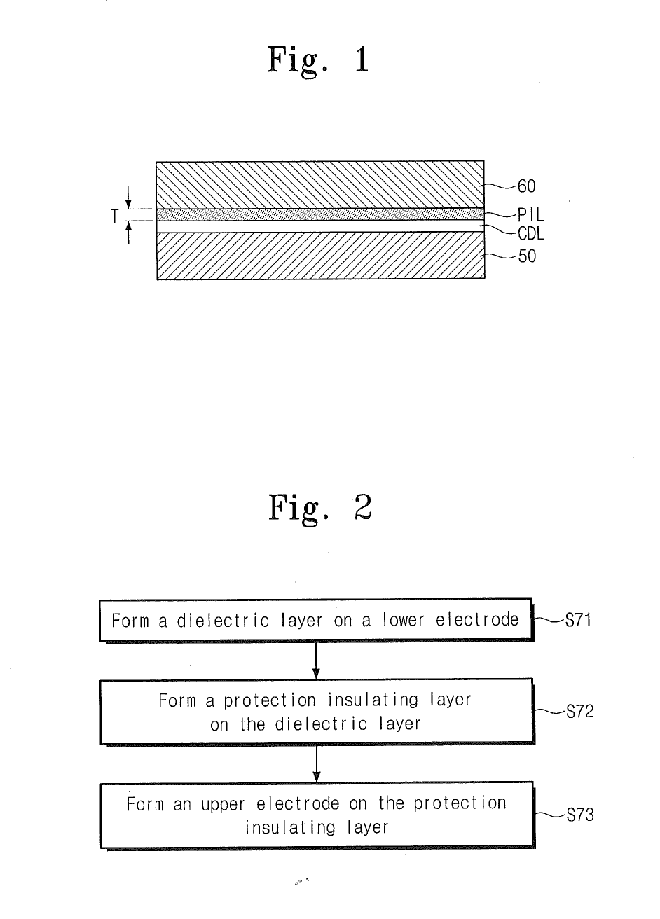

FIG. 1 is a cross-sectional view illustrating a capacitor included in a semiconductor device according to some embodiments of the inventive concepts.

Referring to FIG. 1, a semiconductor device according to embodiments may include a capacitor. The capacitor includes a lower electrode 50, a capacitive dielectric layer CDL on the lower electrode 50, a protection insulating layer PIL on the capacitive dielectric layer CDL, and an upper electrode 60 on the protection insulating layer PIL. In other words, the capacitive dielectric layer CDL is disposed between the lower electrode 50 and the upper electrode 60, and the protection insulating layer PIL is disposed between the capacitive dielectric layer CDL and the upper electrode 60.

The lower electrode 50 includes at least one of a noble metal and a conductive noble metal oxide. The noble metals are metals that are resistant to corrosion and oxidation in moist air, unlike most base metals. The noble metals are most commonly considered to be ruthenium, rhodium, palladium, silver, osmium, iridium, platinum, and gold. For example, the lower electrode 50 may include at least one of ruthenium (Ru), ruthenium oxide (RuO₂), iridium (Ir), and iridium oxide (IrO₂). In some embodiments, the lower electrode 50 may be in a crystalline state. For example, the lower electrode 50 may have a rutile crystal structure. The lower electrode 50 may have various shapes. In some embodiments, the lower electrode 50 may have a plate-shape. In other embodiments, the lower electrode 50 may have a three-dimensional structure (e.g., a pillar-shape or a cylinder-shape).

The capacitive dielectric layer CDL includes a high-k dielectric material having a high dielectric constant. In particular, the high-k dielectric material may have a high dielectric constant of about 60 or more. In some embodiments, the high-k dielectric material of the capacitive dielectric layer CDL may be titanium oxide (TiO₂). The capacitive dielectric layer CDL may be in a crystalline state. In some embodiments, the capacitive dielectric layer CDL may include the titanium oxide having the rutile crystal structure. Even though the titanium oxide of the rutile crystal structure has a small thickness (e.g., about 60 Å or less), it can have a high dielectric constant of about 60 or more.

The protection insulating layer PIL covers the capacitive dielectric layer CDL. The protection insulating layer PIL includes an insulating oxide capable of protecting the capacitive dielectric layer CDL from a process gas used in a subsequent process performed after the formation of the protection insulating layer PIL. In other words, reactivity between the insulating oxide of the protection insulating layer PIL and the process gas of the subsequent process is lower or weaker than reactivity between the capacitive dielectric layer CDL and the process gas of the subsequent process. In some embodiments, the process gas of the subsequent process may include at least one of argon (Ar), chlorine (Cl₂), and carbon fluoride (CₓF_{y}). Additionally, the insulating oxide of the protection insulating layer PIL may have an excellent incubation characteristic with respect to the upper electrode 60. The incubation characteristic means degree of uniformity and/or a density of seed points for formation of the upper electrode 60. In other words, an excellent incubation characteristic means a high degree of uniformity and/or a high density of the seed points. According to embodiments of the inventive concepts, the insulating oxide of the protection insulating layer PIL may be tantalum oxide (Ta₂O₅). The tantalum oxide has a low reactivity with respect to the process gas of the subsequent process. Additionally, the tantalum oxide has an excellent incubation characteristic.

The protection insulating layer PIL may be in an amorphous state. In other words, the protection insulating layer PIL may include amorphous tantalum oxide. Thus, the protection insulating layer PIL may have an excellent protection function with respect to the capacitive dielectric layer CDL. Additionally, a leakage current through the protection insulating layer PIL may be reduced. In other words, the protection insulating layer PIL in the amorphous state may have an excellent leakage current characteristic.

The protection insulating layer PIL may have a thin thickness T of about 1 Å to about 15 Å. Thus, the influence of the protection insulating layer PIL on a capacitance of the capacitor may be reduced. The protection insulating layer PIL may have a dielectric constant that is smaller than the dielectric constant of the capacitive dielectric layer CDL including the titanium oxide. Since the protection insulating layer PIL has the thin thickness T, the capacitive dielectric layer CDL may provide a primary influence of the capacitance of the capacitor, while the influence of the protection insulating layer PIL on the capacitance may be small compared to the influence of the capacitive dielectric layer CDL on the capacitance of the capacitor. As a result, the protection insulating layer PIL may protect the capacitive dielectric layer CDL and the influence of the protection insulating layer PIL on the capacitance of the capacitor may be relatively small. Additionally, since the thickness T of the protection insulating layer PIL may be in the range of about 1 Å to about 15 Å, the protection insulating layer PIL may maintain an amorphous state.

The protection insulating layer PIL may further include a barrier oxide. The barrier oxide may have an energy band gap greater than an energy band gap of the tantalum oxide of the protection insulating layer PIL. In some embodiments, the energy band gap of the barrier oxide may be equal to or greater than about 5.0 eV. In particular, the energy band gap of the barrier oxide may be in a range of about 5.0 eV to about 10.0 eV. In some embodiments, the barrier oxide includes a specific element and oxygen. For example, the specific element may be at least one of aluminum, zirconium, and hafnium. A concentration of the specific element of the barrier oxide may be in a range of about 0.01 at % to about 50 at % in the protection insulating layer PIL. For example, the barrier oxide may include at least one of aluminum oxide (Al₂O₃), zirconium oxide (ZrO₂), and hafnium oxide (HfO₂). Since the protection insulating layer PIL includes the barrier oxide having the great energy band gap, the leakage current characteristic of the protection insulating layer PIL may be improved.

In an operation mode, the capacitor has a charge accumulating characteristic. Thus, current does not flow between the lower electrode 50 and the upper electrode 60 due to the presence of the capacitive dielectric layer CDL and the protection insulating layer PIL in the operation mode. In other words, the capacitive dielectric layer CDL and the protection insulating layer PIL may block current flow between the lower electrode 50 and the upper electrode 60.

Furthermore, the capacitive dielectric layer CDL may further include an additive oxide in order to improve a leakage current characteristic of the capacitive dielectric layer CDL. In other words, the capacitive dielectric layer CDL may include the titanium oxide and the additive oxide. The additive oxide may have an energy band gap that is greater than an energy band gap of the titanium oxide. In some embodiments, the energy band gap of the additive oxide may be equal to or greater than about 5.0 eV. In particular, the energy band gap of the additive oxide may be in a range of about 5.0 eV to about 10.0 eV. The additive oxide includes an additive element and oxygen. For example, the additive element may be at least one of aluminum, zirconium, and hafnium. A concentration of the additive element of the additive oxide may be in a range of about 0.01 at % to about 30 at % in the capacitive dielectric layer CDL. For example, the additive oxide may include at least one of aluminum oxide (Al₂O₃), zirconium oxide (ZrO₂), and hafnium oxide (HfO₂).

The upper electrode 60 is disposed on the protection insulating layer PIL. The upper electrode 60 covers the lower electrode 50. The upper electrode 60 may include at least one of a noble metal and a conductive noble metal oxide. For example, the upper electrode 60 may include at least one of ruthenium (Ru), ruthenium oxide (RuO₂), iridium (Ir), and iridium oxide (IrO₂). In some embodiments, the upper electrode 60 may be in a crystalline state. For example, the upper electrode 60 may have a rutile crystal structure. As described above, the protection insulating layer PIL has the excellent incubation characteristic. Thus, the upper electrode 60 may have a dense structure. As a result, a leakage current characteristic of the upper electrode 60 may be improved.

As mentioned above, the protection insulating layer PIL including the tantalum oxide and the barrier oxide is disposed between the upper electrode 60 and the capacitive dielectric layer CDL including the titanium oxide such that the protection insulating layer PIL protects the capacitive dielectric layer CDL. Thus, the capacitive dielectric layer CDL may be protected from the process gas of the subsequent process. Additionally, the leakage current characteristic of the protection insulating layer PIL may be more improved due to the barrier oxide. As a result, the capacitive dielectric layer CDL may have excellent electrical characteristics.

If the protection insulating layer PIL is omitted, the capacitive dielectric layer CDL may be damaged or modified by the process gas of the subsequent process, so that oxygen vacancies may be generated in the capacitive dielectric layer CDL. In this case, the oxygen vacancies may act as a path of a leakage current. Additionally, the titanium oxide of the capacitive dielectric layer CDL may have a rutile crystal structure in order to have a high dielectric constant. In this case, a boundary of grains of the titanium oxide may also act as a path of the leakage current. However, according to some embodiments of the inventive concepts, the protection insulating layer PIL protects the capacitive dielectric layer CDL from the process gas of the subsequent process to reduce or prevent damage to the capacitive dielectric layer CDL. Additionally, since the protection insulating layer PIL is in the amorphous state, the protection insulating layer PIL may block the leakage current passing through the boundary of the grains of the capacitive dielectric layer CDL.

The capacitor may be used as one of various components in the semiconductor device. In the event that the semiconductor device is a semiconductor memory device (e.g., a dynamic random access memory (DRAM) device), the capacitor may be used as a memory component of a unit cell. Alternatively, in the event that the semiconductor device is a logic device, the capacitor may be used as one of components constituting a logic circuit.

Next, a method of forming the capacitor will be described with reference to FIG. 2. FIG. 2 is a flowchart illustrating a method of manufacturing the capacitor of FIG. 1.

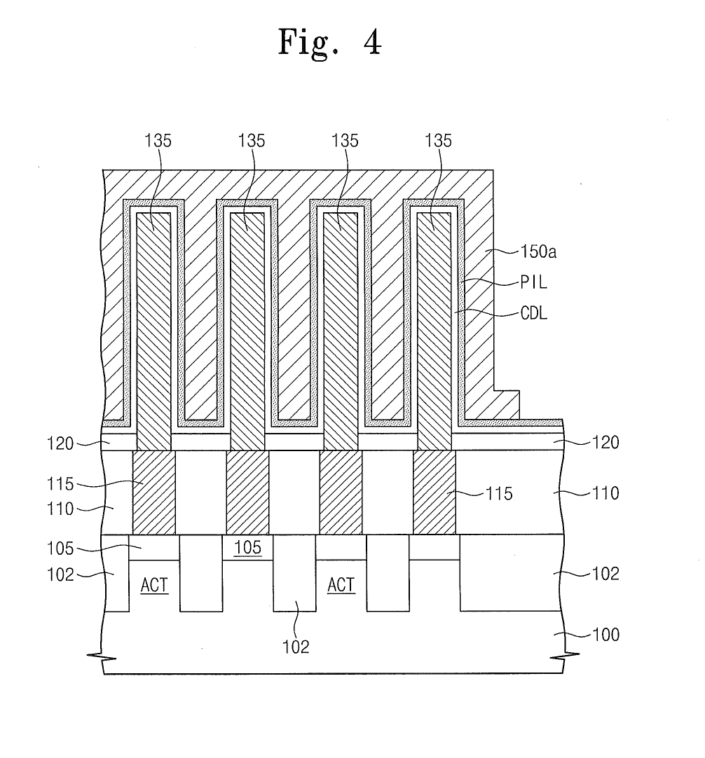

Referring to FIGS. 1 and 2, the lower electrode 50 may be formed on a substrate (see substrate 100 of FIGS. 4 to 19) for manufacturing a semiconductor device. In particular, the lower electrode 50 may be formed on an insulating layer (see layer 110 of FIGS. 4 to 19) stacked on the substrate. The lower electrode 50 may be formed, for example, using a chemical vapor deposition (CVD) process or an atomic layer deposition (ALD) process. As described above, the lower electrode 50 may be formed to include at least one of a noble metal and a conductive noble metal oxide. The lower electrode 50 may have the rutile crystal structure.

The capacitive dielectric layer CDL is formed on the lower electrode 50 (S71). The capacitive dielectric layer CDL is formed, for example, by a chemical vapor deposition (CVD) process or an atomic layer deposition (ALD) process. As described above, the capacitive dielectric layer CDL includes the titanium oxide. At this time, the capacitive dielectric layer CDL may be formed using the lower electrode 50 as a seed. Thus, the capacitive dielectric layer CDL including the titanium oxide may also have the rutile crystal structure.

In some embodiments, the lower electrode 50 may be formed of ruthenium (Ru), and a surface of the lower electrode 50 may be oxidized in an initial stage of the formation of the capacitive dielectric layer CDL to form ruthenium oxide. In this case, the lower electrode 50 may include the ruthenium and the ruthenium oxide formed on the surface of the ruthenium. In other embodiments, an entire portion of the lower electrode 50 may be formed of ruthenium oxide before the formation of the capacitive dielectric layer CDL.

In some embodiments, the capacitive dielectric layer CDL is formed by the atomic layer deposition (ALD) process. In more detail, a titanium source gas may be supplied into a process chamber in which the substrate having the lower electrode 50 is loaded. The supplied titanium source gas may be adsorbed on a surface of the lower electrode 50. A non-adsorbed titanium source gas may be purged. Thereafter, an oxygen source gas (e.g., an ozone gas) may be supplied into the process chamber. The supplied oxygen source gas may react with the adsorbed titanium source gas to form the titanium oxide. Subsequently, an unreacted oxygen source gas and a reaction byproduct may be purged. The four steps described above may constitute one cycle, and the cycle may be repeated plural times.

The capacitive dielectric layer CDL including the additive oxide and the titanium oxide may be formed by the atomic layer deposition (ALD) process. In more detail, the titanium source gas may be supplied into the process chamber and then a non-adsorbed titanium source gas may be purged. The oxygen source gas may be supplied into the process chamber and then an unreacted oxygen source gas and a reaction byproduct may be purged. The cycle consisting of the four steps may be repeatedly performed at least one time. Thereafter, an additive element source gas may be supplied into the process chamber. The additive element source gas includes the additive element (e.g., aluminum, zirconium, and/or hafnium) of the additive oxide. Subsequently, a non-adsorbed additive element source gas may be purged and then the oxygen source gas may be supplied into the process chamber. An unreacted oxygen source gas and a reaction byproduct may be purged. Thereafter, the cycle of the supplying and purging of the titanium source gas and the supplying and purging of the oxygen source gas may be repeatedly performed at least one time. The order and number of the supplying of the additive element source gas may be controlled depending on demand characteristics of the capacitive dielectric layer CDL. In other embodiments, the titanium source gas and the additive element source gas may be supplied together in the atomic layer deposition (ALD) process.

In still other embodiments, the capacitive dielectric layer CDL may be formed by the chemical vapor deposition (CVD) process using a titanium source gas and an oxygen source gas or using a titanium source gas, an additive element source gas and an oxygen source gas.

The protection insulating layer PIL is formed on the capacitive dielectric layer CDL (S72). The protection insulating layer PIL is formed by at least one of a chemical vapor deposition (CVD) process and an atomic layer deposition (ALD) process. As described above, the protection insulating layer PIL may include the tantalum oxide and may have a thickness T of about 1 Å to about 15 Å. Additionally, the protection insulating layer PIL may be formed to have the amorphous state.

In some embodiments, the protection insulating layer PIL may be formed by the atomic layer deposition (ALD) process. In more detail, the substrate having the capacitive dielectric layer CDL is loaded into a process chamber. A tantalum source gas is supplied into the process chamber. The tantalum source gas may be adsorbed on a surface of the capacitive dielectric layer CDL. Subsequently, a non-adsorbed tantalum source gas may be purged. Thereafter, an oxygen source gas (e.g., an ozone gas) is supplied into the process chamber. The supplied oxygen source gas may react with the adsorbed tantalum source gas to form the tantalum oxide. Subsequently, an unreacted oxygen source gas and a reaction byproduct may be purged. A cycle including the supplying and purging of the tantalum source gas and the supplying and purging of the oxygen source gas may be repeated plural times in order that the thickness T of the protection insulating layer PIL may be in the range of about 1 Å to about 15 Å.

The protection insulating layer PIL including the barrier oxide and the tantalum oxide may be formed by the atomic layer deposition (ALD) process. In more detail, the tantalum source gas may be supplied into the process chamber in a first step. A non-adsorbed tantalum source gas may be purged in a second step. The oxygen source gas may be supplied into the process chamber in a third step. An unreacted oxygen source gas and a reaction byproduct may be purged in a fourth step. A specific element source gas may be supplied into the process chamber in a fifth step. The specific element source gas includes the specific element (e.g., aluminum, zirconium, and/or hafnium) of the barrier oxide. The specific element source gas may be adsorbed on the capacitive dielectric layer CDL. A non-adsorbed specific element source gas may be purged in a sixth step. The oxygen source gas may be supplied into the process chamber in a seventh step. The oxygen source gas of the seventh step may react with the adsorbed specific element source gas to form the barrier oxide. An unreacted oxygen source gas and a reaction byproduct may be purged in an eighth step. A cycle including the first to fourth steps may be repeated plural times before the fifth step is performed. The cycle including the first to fourth steps may be repeated at least one time again after the eighth step is performed.

Alternatively, the tantalum source gas and the specific element source gas may be supplied together in the first step. In this case, the fifth to eighth steps may be omitted.

In other embodiments, the protection insulating layer PIL may be formed by the chemical vapor deposition (CVD) process using a tantalum source gas and an oxygen source gas or using a tantalum source gas, an oxygen source gas and a specific element source gas.

As described above, the protection insulating layer PIL may be formed to have the thin thickness T of the about 1 Å to about 15 Å. Thus, the protection insulating layer PIL may have the amorphous state. If the protection insulating layer PIL has a thickness of about 20 Å or more, the protection insulating layer PIL may have a crystalline state. Particularly, if an annealing process of about 500 degrees Celsius is performed on the protection insulating layer PIL having the thickness of about 20 Å or more, the protection insulating layer PIL may be formed in the crystalline state. In this case, the leakage current characteristic of the capacitor and/or characteristics of the capacitive dielectric layer CDL may be deteriorated. However, the protection insulating layer PIL according to the embodiments has the thin thickness T of about 1 Å to about 15 Å to maintain its amorphous state, as mentioned above.

An annealing process is not performed for the formation of the protection insulating layer PIL. In other words, an annealing process is not performed on the protection insulating layer PIL. Thus, the protection insulating layer PIL may maintain its amorphous state. Additionally, it is possible to reduce or minimize a thermal budget supplied to the protection insulating layer PIL, the capacitive dielectric layer CDL and the lower electrode 50. As a result, characteristic deterioration of the lower electrode 50, the capacitive dielectric layer CDL and the protection insulating layer PIL may be reduced or prevented.

The upper electrode 60 is formed on the protection insulating layer PIL (S73). In more detail, an upper electrode layer may be deposited on the protection insulating layer PIL and the deposited upper electrode layer may be patterned to form the upper electrode 60. The patterning process for the formation of the upper electrode 60 may include a photolithography process and an etching process. The protection insulating layer PIL protects the capacitive dielectric layer CDL from a process gas (e.g., argon (Ar), chlorine (Cl₂), and/or carbon fluoride (CₓF_{y})) used in the etching process of the patterning process.

Additionally, the protection insulating layer PIL may protect the capacitive dielectric layer CDL from process gases of subsequent processes (e.g., a deposition process of a subsequent layer such as an interlayer insulating layer and/or a conductive layer and/or a patterning process performed on the subsequent layer) performed after the formation of the upper electrode 60.

The upper electrode layer may be formed by an atomic layer deposition (ALD) process or a chemical vapor deposition (CVD) process. At this time, the upper electrode layer may have a dense structure due to the excellent incubation characteristic of the tantalum oxide included in the protection insulating layer PIL. The upper electrode layer may be formed to have the rutile crystal structure.

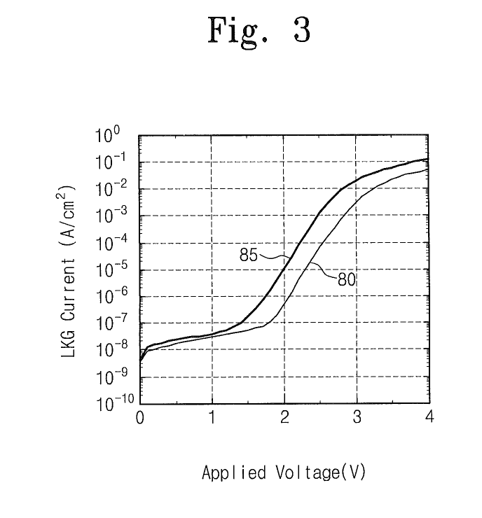

Experiments were performed in order to verify the characteristics of the capacitor according to embodiments of the inventive concepts. The leakage current characteristic of the capacitor was evaluated through a first experiment. In the first experiment, a first sample and a second sample were prepared. The first sample was manufactured to including a lower electrode (ruthenium oxide), a dielectric layer (titanium oxide) on the lower electrode, a protection insulating layer (tantalum oxide), and an upper electrode (ruthenium oxide) on the protection insulating layer. In other words, the first sample was manufactured to include the capacitor according to embodiments of the inventive concepts. The second sample was manufactured to include a lower electrode (ruthenium oxide), a dielectric layer (titanium oxide) on the lower electrode, and an upper electrode (ruthenium oxide) on the dielectric layer. In other words, the second sample does not include the protection insulating layer according to the embodiments of the inventive concepts. The capacitors of the first and second samples were patterned using an etching gas including argon (Ar), chlorine (Cl₂) and nitrogen (N₂). A total equivalent oxide thickness of the dielectric layer and the protection insulating layer was about 5.1 Å in the first sample. An equivalent oxide thickness of the dielectric layer was about 5.2 Å in the second sample. In other words, the equivalent oxide thickness of the first sample was substantially equal to the equivalent oxide thickness of the second sample. Leakage current characteristics of the first and second samples were illustrated in FIG. 3.

FIG. 3 is a graph illustrating characteristics of a capacitor according to example embodiments of the inventive concepts.

Referring to FIG. 3, a first line 80 shows the leakage current characteristic of the first sample and a second line 85 shows the leakage current characteristic of the second sample. As shown in FIG. 3, a voltage of the first sample was higher than a voltage of the second sample by about 0.4V with respect to a leakage current of 100 nA. Thus, it was confirmed that the leakage current characteristic of the sample 1 was improved.

Next, a second experiment was performed in order to confirm improvement in the reliability of the capacitor according to embodiments of the inventive concepts. In the second experiment, a leakage current behavior test was performed on each of the first and second samples. A leakage current measurement was repeatedly performed 50 times in each of the leakage current behavior tests. The leakage current of the capacitor was measured by sweeping a voltage in each of the leakage current measurements. According to the result of the leakage current behavior test, a soft break down of the first sample occurred at about 1.9V (volt) and a soft break down of the second sample occurred at about 1.1V. Thus, it was confirmed that the reliability of the first sample (i.e., the embodiment) was improved. As a result, it may be confirmed that the leakage current characteristic and the reliability of the capacitor are improved due to the protection insulating layer PIL according to embodiments of the inventive concepts.

Next, various embodiments of semiconductor devices include the capacitor described above will be mentioned with reference to the drawings.

FIG. 4 is a cross-sectional view illustrating a semiconductor device including a capacitor according to some embodiments of the inventive concepts.

Referring to FIG. 4, an interlayer insulating layer 110 may be disposed on a substrate 100. The substrate 100 may be a semiconductor substrate (e.g., a silicon substrate). The interlayer insulating layer 110 may include a silicon oxide layer. Contact plugs 115 may penetrate the interlayer insulating layer 110. Each of the contact plugs 115 may be connected to one terminal of each of switching components formed on the substrate 100 under the interlayer insulating layer 110. In some embodiments, the switching component may be a field effect transistor. In other embodiments, the switching component may be a PN diode.

In some embodiments, a device isolation pattern 102 may be disposed in or on the substrate 100 to define active regions ACT. The device isolation pattern 102 may be a trench-type device isolation pattern. The device isolation pattern 102 may include an insulating material (e.g., silicon oxide, silicon nitride, and/or silicon oxynitride). Dopant doped regions 105 may be formed in the active regions ACT. The contact plugs 115 may be connected to the dopant doped regions 105, respectively. Each of the dopant doped regions 105 may correspond to one terminal (e.g., a drain region or a source region) of the field effect transistor.

An etch stop layer 120 may be disposed on the interlayer insulating layer 110. The etch stop layer 120 may include an insulating material having an etch selectivity with respect to the interlayer insulating layer 110. For example, the etch stop layer 120 may include a silicon nitride layer and/or a silicon oxynitride layer.

Lower electrodes 135 may be disposed on the interlayer insulating layer 110 to penetrate the etch stop layer 120. The lower electrodes 135 may be connected to the contact plugs 115, respectively. The lower electrodes 135 may have pillar-shapes. The lower electrodes 135 protrude upward from the etch stop layer 120. Bottom end portions of the lower electrodes 135 may penetrate the etch stop layer 120 to be connected to the contact plugs 115, respectively.

The lower electrodes 135 may be formed of the same material as the lower electrode 50 of FIG. 1. Additionally, the lower electrodes 135 may have the same characteristics as the lower electrode 50 of FIG. 1. The lower electrodes 135 may have the rutile crystal structure.

The capacitive dielectric layer CDL described with reference to FIGS. 1 and 2 are disposed on surfaces of the lower electrodes 135. The capacitive dielectric layer CDL may be conformally disposed along the surfaces of the lower electrodes 135. The protection insulating layer PIL described with reference to FIGS. 1 and 2 is disposed on the capacitive dielectric layer CDL. The protection insulating layer PIL may also be conformally disposed along the surfaces of the lower electrodes 135.

An upper electrode 150a may be disposed on the protection insulating layer PIL. The upper electrode 150a covers the surfaces of the lower electrodes 135. The upper electrode 150a may have the same material and the same characteristics as the upper electrode 60 of FIG. 1. The upper electrode 150a may also have the rutile crystal structure. A capacitor of the semiconductor device according to the present embodiment includes the lower electrode 135, the capacitive dielectric layer CDL, the protection insulating layer PIL and the upper electrode 150a. The semiconductor device according to the present embodiment may be a dynamic random access memory (DRAM) device.

According to the semiconductor device described above, the protection insulating layer PIL protects the capacitive dielectric layer CDL such that the capacitive dielectric layer CDL may have excellent electrical characteristics. The protection insulating layer PIL may have a small thickness and may be in an amorphous state. Thus, the capacitor may have an excellent leakage current characteristic and excellent reliability. Additionally, the lower electrode 135 has the three-dimensional structural pillar-shape. Thus, an overlapping area between the lower and upper electrodes 135 and 150a may be increased such that a capacitance of the capacitor may be increased. As a result, the semiconductor device having excellent reliability and/or a high integration degree may be realized.

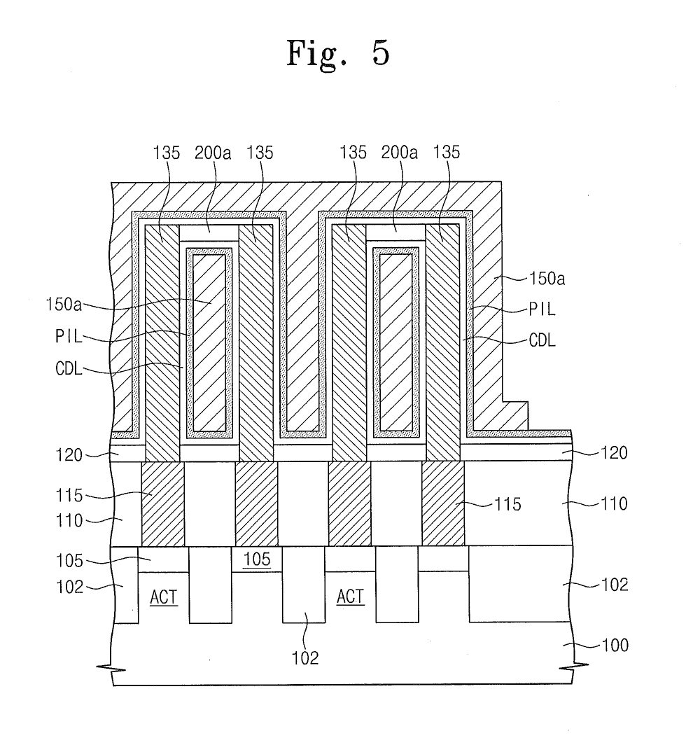

FIG. 5 is a cross-sectional view illustrating a semiconductor device including a capacitor according to other embodiments of the inventive concepts.

Referring to FIG. 5, a semiconductor device according to the present embodiment may further include a supporting pattern 200a disposed between the lower electrodes 135. In some embodiments, the supporting pattern 200a may be disposed between top end portions of the lower electrodes 135. The supporting pattern 200a may be in contact with the lower electrodes 135. The supporting pattern 200a is formed of an insulating material (e.g., silicon nitride and/or silicon oxynitride).

The capacitive dielectric layer CDL and the protection insulating layer PIL may cover of another surface of the lower electrode 135, which is not in contact with the supporting pattern 200a. Additionally, the capacitive dielectric layer CDL and the protection insulating layer PIL may also cover a top surface and a bottom surface of the supporting pattern 200a.

The lower electrodes 135 may be supported by the supporting pattern 220a to prevent a leaning phenomenon of the lower electrodes 135 having high heights. Because the supporting pattern 200a is formed of the insulating material, the lower electrodes 135 are electrically insulated from each other.

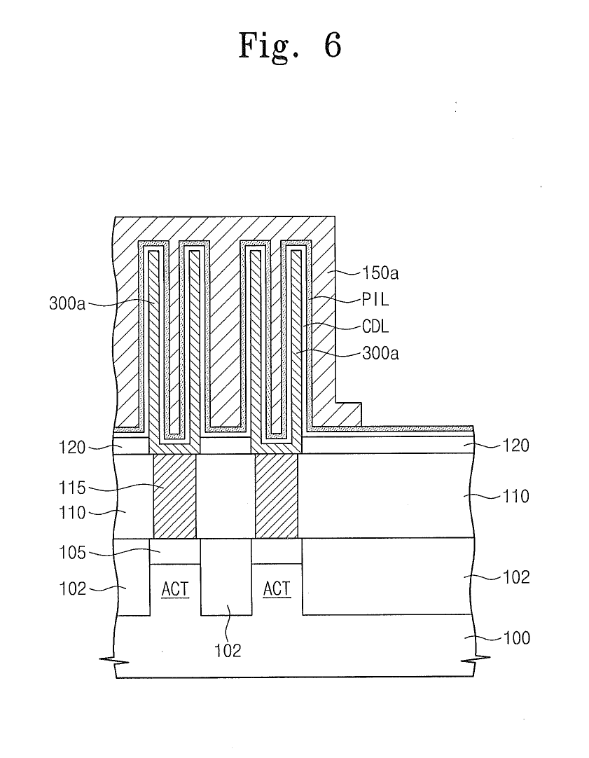

FIG. 6 is a cross-sectional view illustrating a semiconductor device including a capacitor according to still other embodiments of the inventive concepts.

Referring to FIG. 6, a lower electrode 300a according to the present embodiment may have a hollow cylinder-shape. Thus, the lower electrode 300a may have an inner surface and an outer surface. The capacitive dielectric layer CDL and the protection insulating layer PIL may cover all of the inner and outer surfaces of the lower electrode 300a. The upper electrode 150a may be disposed on the protection insulating layer PIL and may cover the inner and outer surfaces of the lower electrode 300a. Thus, an overlapping area of the lower and upper electrodes 300a and 150a may be more increased such that a capacitance of a capacitor including the lower and upper electrodes 300a and 150a may be more increased. The lower electrode 300a may have the same material and the same characteristics as the lower electrode 50 illustrated in FIG. 1.

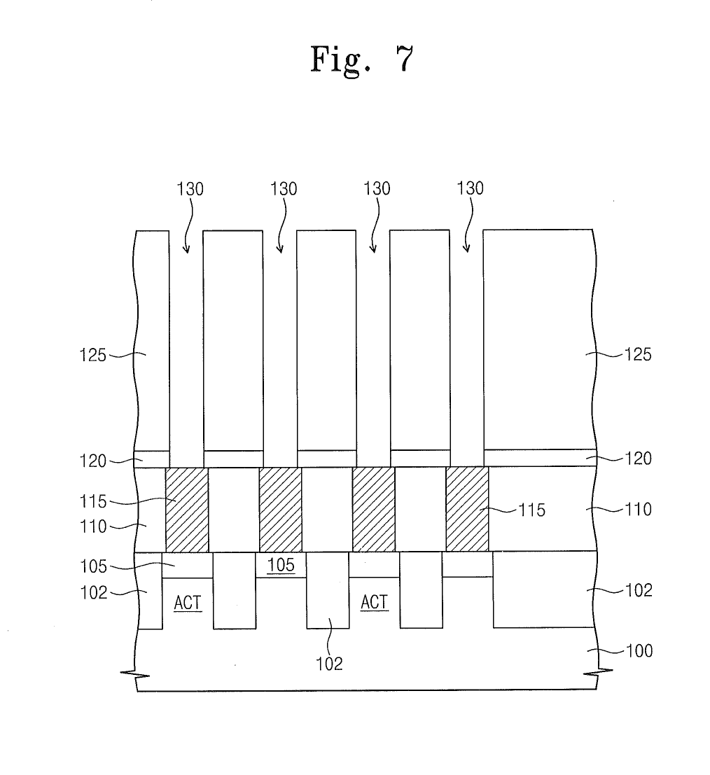

FIGS. 7 to 12 are cross-sectional views illustrating a method of manufacturing a semiconductor device including a capacitor according to some embodiments of the inventive concepts.

Referring to FIG. 7, a device isolation pattern 102 may be formed in or on a substrate 100 to define active regions ACT. Dopant doped regions 105 may be formed in the active regions ACT. Gate patterns (not shown) may be formed to cross the active regions ACT before the formation of the dopant doped regions 105.

An interlayer insulating layer 110 may be formed on the substrate 100. Contact plugs 115 may be formed to penetrate the interlayer insulating layer 110. The contact plugs 115 may be connected to the dopant doped regions 105, respectively. The contact plugs 115 are formed of a conductive material. For example, the contact plugs 115 may include at least one of a doped semiconductor material (e.g., doped silicon), a metal (e.g., titanium, tantalum, and/or tungsten), a conductive metal nitride (e.g., titanium nitride, tantalum nitride, and/or tungsten nitride), and a metal-semiconductor compound (e.g., a metal sificide).

Next, an etch stop layer 120 and a mold layer 125 may be sequentially formed on the interlayer insulating layer 110. The etch stop layer 120 may be formed of an insulating material having an etch selectivity with respect to the interlayer insulating layer 110 and the mold layer 125. For example, the etch stop layer 120 may be formed of a silicon nitride layer and/or a silicon oxynitride layer, and the interlayer insulating layer 110 and the mold layer 125 may be formed of silicon oxide layers.

Node holes 130 may be formed to successively penetrate the mold layer 125 and the etch stop layer 120. The node holes 130 may expose the contact plugs 115, respectively. When the mold layer 125 is patterned in order to form the node holes 130, etch damage of the contact plugs 130 may be minimized by the etch stop layer 120.

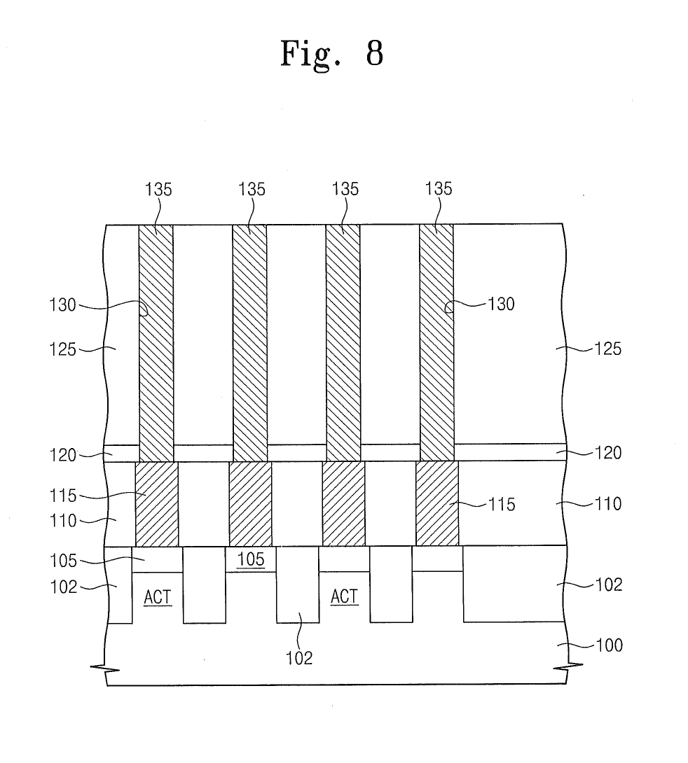

Referring to FIG. 8, a lower electrode layer may be formed to fill the node holes 130. As described with reference to FIGS. 1 and 2, the lower electrode layer may include at least one of a noble metal and a conductive noble metal oxide and may have a crystalline state (e.g., the rutile crystal structure). The lower electrode layer may be formed by the atomic layer deposition (ALD) process or chemical vapor deposition (CVD) process described with reference to FIGS. 1 and 2.

The lower electrode layer may be planarized until the mold layer 125 is exposed, thereby forming lower electrodes 135. The lower electrode layer may be planarized by an etch-back process or a chemical mechanical polishing (CMP) process.

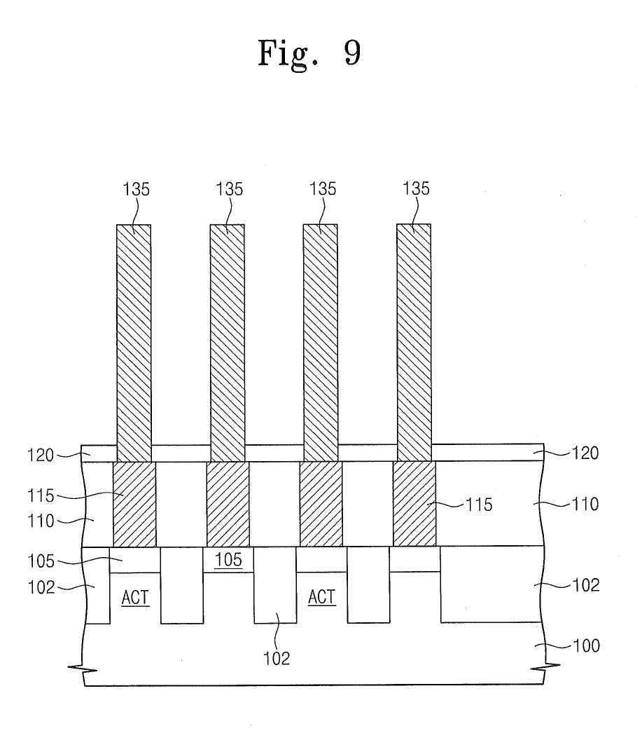

Referring to FIG. 9, the mold layer 125 may be removed to expose sidewalls of the lower electrodes 135. At this time, the etch stop layer 120 protects the interlayer insulating layer 110. The mold layer 125 may be removed by an isotropic etching process (e.g., a wet etching process).

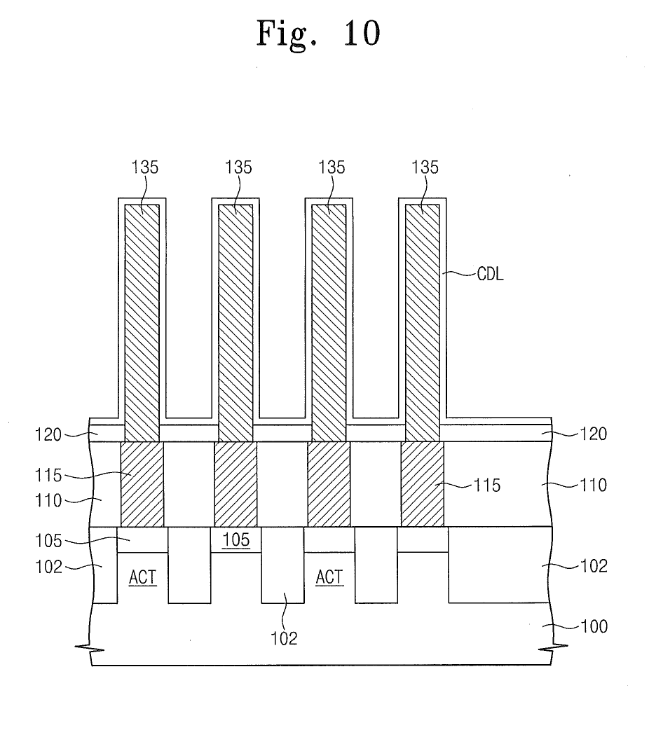

Referring to FIG. 10, the capacitive dielectric layer CDL described with reference to FIGS. 1 and 2 may be formed on exposed surfaces of the lower electrodes 135. As described with reference to FIGS. 1 and 2, the capacitive dielectric layer CDL may be formed by the atomic layer deposition (ALD) process or chemical vapor deposition (CVD) process. Thus, the capacitive dielectric layer CDL may be conformally formed on the exposed surfaces of the lower electrodes 135 having the three-dimensional structural pillar-shapes.

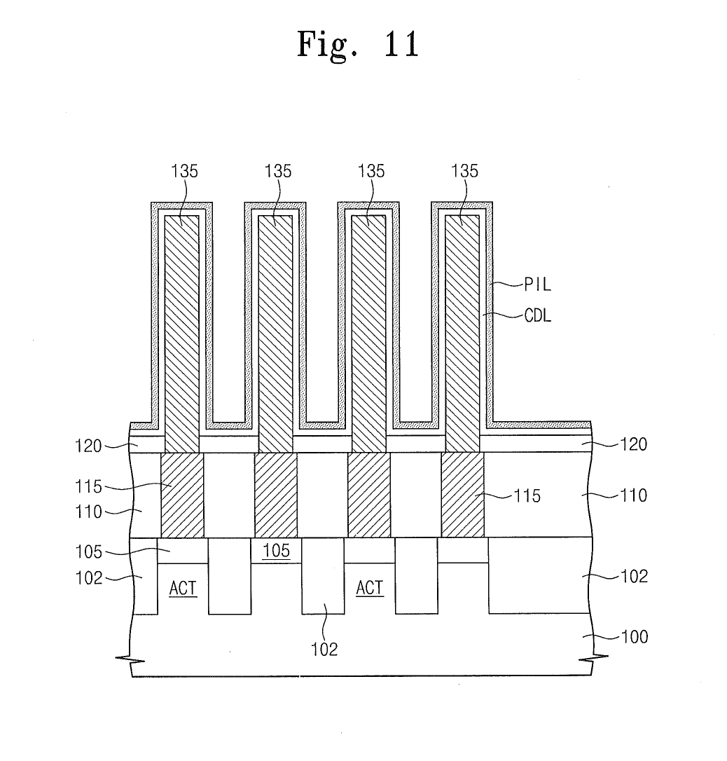

Referring to FIG. 11, the protection insulating layer PIL mentioned with reference to FIGS. 1 and 2 may be formed on the capacitive dielectric layer CDL. As described with reference to FIGS. 1 and 2, the protection insulating layer PIL may be formed by the atomic layer deposition (ALD) process or chemical vapor deposition (CVD) process. Thus, the protection insulating layer PIL may be conformally formed along the surfaces of the lower electrodes 135 on the capacitive dielectric layer CDL.

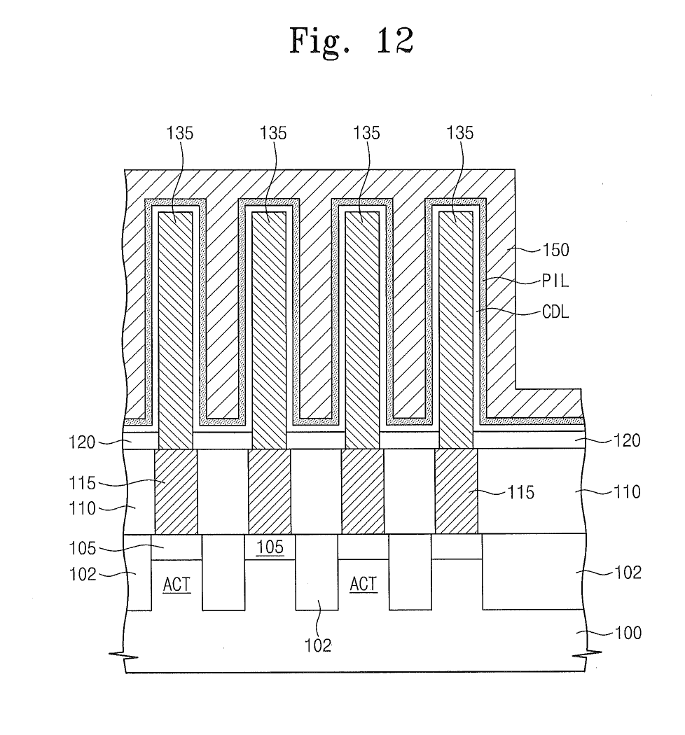

Referring to FIG. 12, an upper electrode layer 150 may be formed on the protection insulating layer PIL. The upper electrode layer 150 includes at least one of a noble metal and a conductive noble metal oxide. The upper electrode layer 150 may be formed by an atomic layer deposition (ALD) process or a chemical vapor deposition (CVD) process. Thus, the upper electrode layer 150 may be formed to have a sufficient thickness in a space between the lower electrodes 135. In some embodiments, the upper electrode layer 150 may fill the space between the lower electrodes 135. The upper electrode layer 150 may be formed to have a dense crystal structure (e.g., the rutile crystal structure) by the excellent incubation characteristic of the protection insulating layer PIL.

The upper electrode layer 150 may be patterned to form the upper electrode 150 of FIG. 4. At this time, the protection insulating layer PIL protects the capacitive dielectric layer CDL. Thus, a capacitor having excellent characteristics may be manufactured. Additionally, the protection insulating layer PIL may protect the capacitive dielectric layer CDL from process gases of subsequent processes after the formation of the upper electrodes 150a. For example, the subsequent processes may include deposition processes and/or patterning processes of an upper interlayer insulating layer and/or an upper conductive layer. As illustrated in FIG. 4, the protection insulating layer PIL may be used as an etch stop layer when the upper electrode layer 150 is patterned.

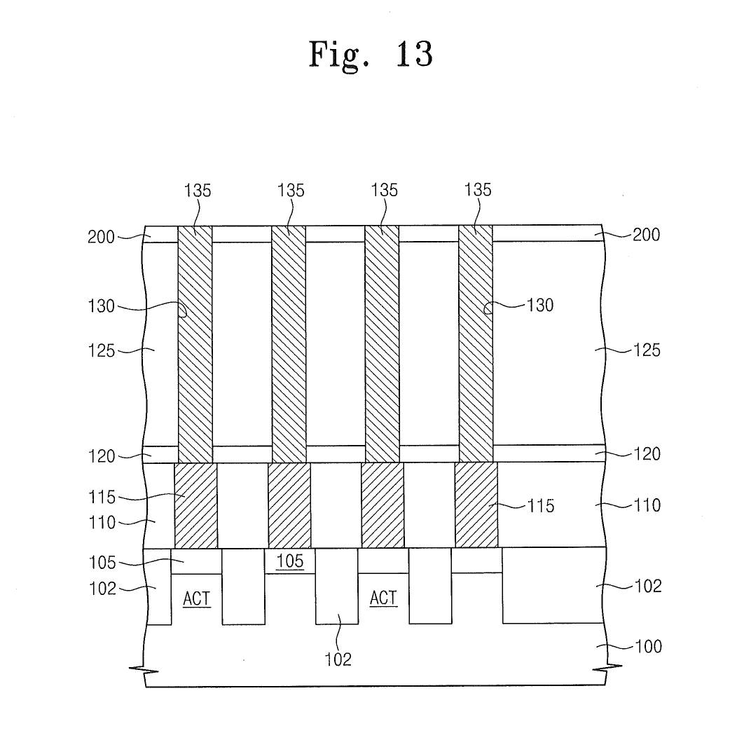

FIGS. 13 to 16 are cross-sectional views illustrating a method of manufacturing a semiconductor device including a capacitor according to other embodiments of the inventive concepts.

Referring to FIG. 13, a supporting layer 200 may be formed on the mold layer 125 before the node holes 130 of FIG. 7 are formed. The supporting layer 200 is formed of an insulating material having an etch selectivity with respect to the mold layer 125. For example, the supporting layer 200 may be formed of a silicon nitride layer and/or a silicon oxynitride layer.

Node holes 130 may be formed to successively penetrate the supporting layer 200, the mold layer 125 and the etch stop layer 120 after the formation of the supporting layer 200. Next, lower electrodes 135 may be formed in the node holes 130, respectively.

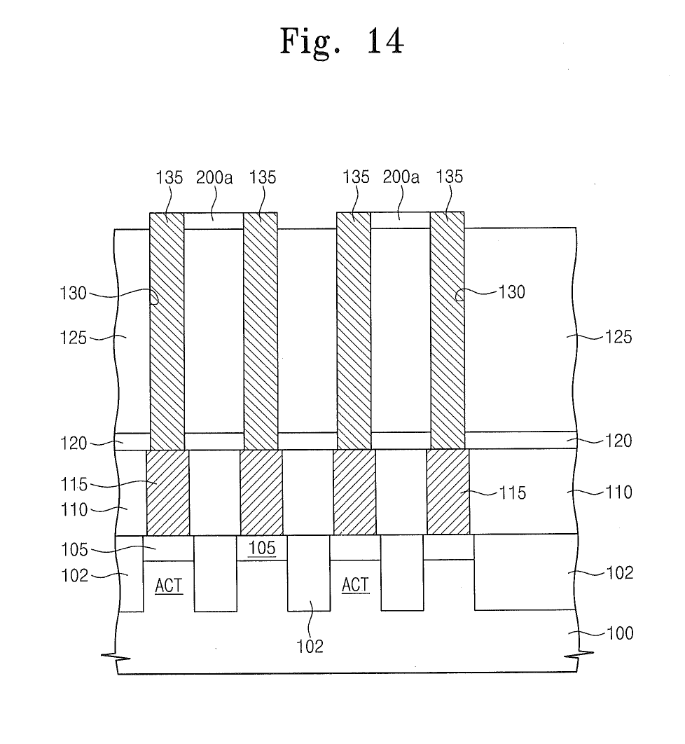

Referring to FIG. 14, the supporting layer 200 may be patterned to form a supporting pattern 200a. At this time, a top surface of the mold layer 125 may be partially exposed. The supporting pattern 200a may be formed between the lower electrodes 135. The supporting pattern 200a may be in contact with sidewalls of top end portions of the lower electrodes 135.

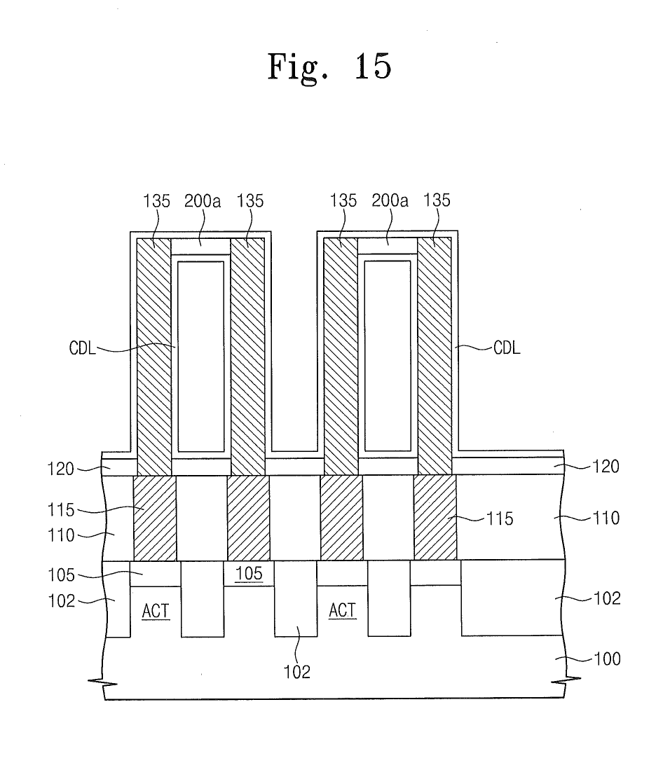

Referring to FIG. 15, an isotropic etching process is performed on the exposed mold layer 125 to remove the exposed mold layer 125. An entire portion of the mold layer 125 under the supporting pattern 200a is removed by the isotropic etching process.

Subsequently, the capacitive dielectric layer CDL is formed by the atomic layer deposition (ALD) process or the chemical vapor deposition (CVD) process. Thus, the capacitive dielectric layer CDL may be conformally formed on the exposed surfaces of the lower electrodes 135 and an exposed surface of the supporting pattern 200a.

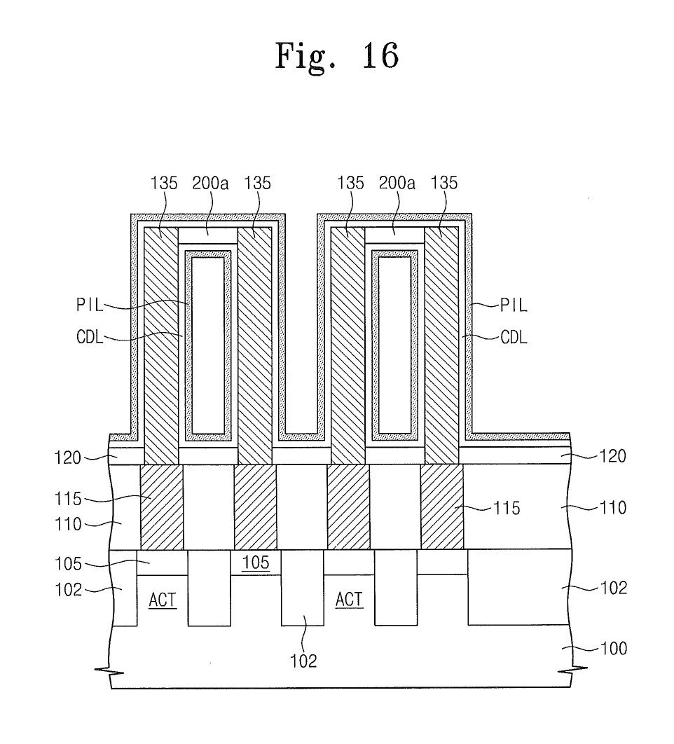

Referring to FIG. 16, the protection insulating layer PIL is formed on the capacitive dielectric layer CDL by the atomic layer deposition (ALD) process or the chemical vapor deposition (CVD) process. Thus, the protection insulating layer PIL may also be conformally formed along the surfaces of the lower electrodes 135 and the surface of the supporting pattern 200a on the capacitive dielectric layer CDL.

Next, an upper electrode layer is formed on the protection insulating layer PIL. The upper electrode layer may be patterned to form the upper electrode 150a of FIG. 5. The upper electrode layer may be formed by an atomic layer deposition (ALD) process or a chemical vapor deposition (CVD) process. Thus, the upper electrode 150a may also cover the surfaces of the lower electrodes 135 under the supporting pattern 200a.

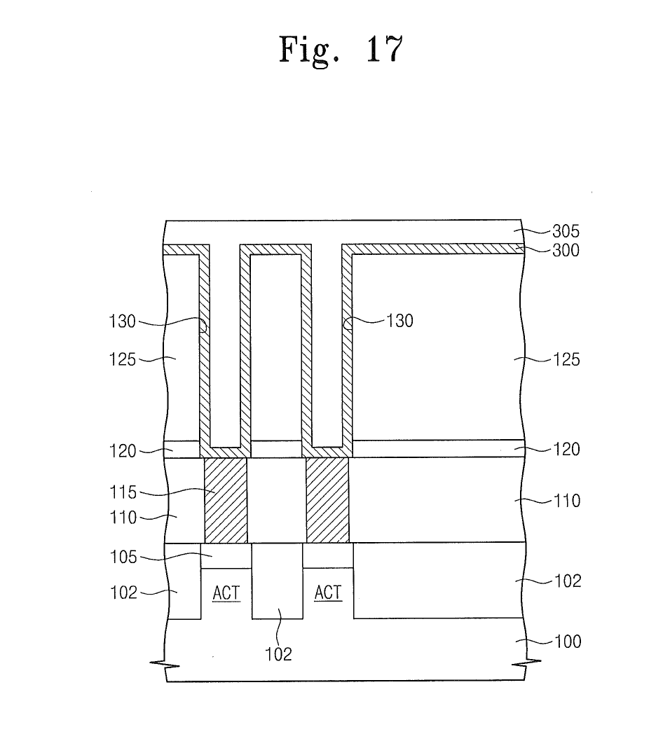

FIGS. 17 to 19 are cross-sectional views illustrating a method of manufacturing a semiconductor device including a capacitor according to still other embodiments of the inventive concepts.

Referring to FIG. 17, the node holes 130 may be formed to successively penetrate the mold layer 125 and the etch stop layer 120, as described with reference to FIG. 7. A lower electrode layer 300 may be conformally formed on the substrate 100 having the node holes 130. The lower electrode layer 300 may be formed by an atomic layer deposition (ALD) process or a chemical vapor deposition (CVD) process. As illustrated in FIG. 17, the lower electrode layer 300 may be conformally formed on inner surfaces of the node holes 130 and may partially fill the node holes 130. The lower electrode layer 300 may have the same material and the same characteristics as the lower electrode 50 of FIG. 1.

A filling layer 305 may be formed on the lower electrode layer 300 to fill the node holes 130. The filling layer 305 may be formed of a material having an etch selectivity with respect to the etch stop layer 120. For example, the filling insulating layer 305 may be formed of a silicon oxide layer.

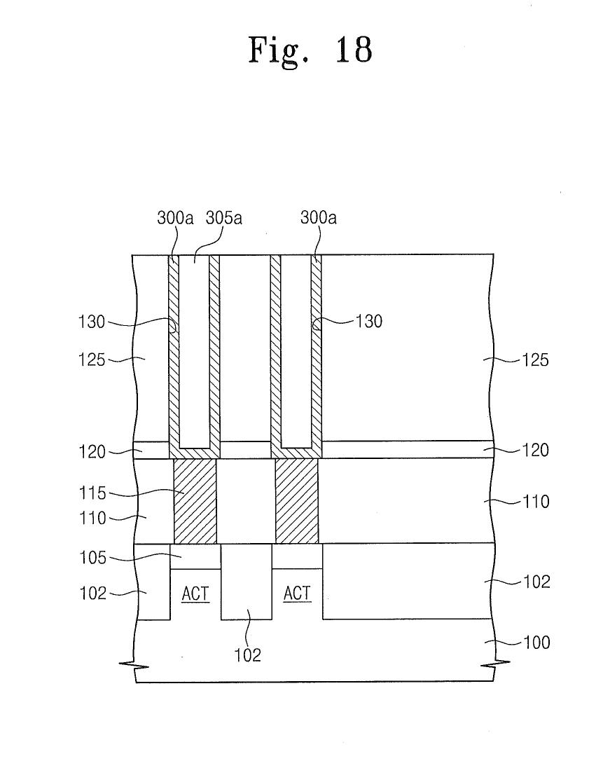

Referring to FIG. 18, the filling layer 305 and the lower electrode layer 300 may be planarized until the mold layer 125 is exposed, thereby forming a lower electrode 300a and a filling pattern 305a in each of the node holes 130. The lower electrode 300a may have a hollow cylinder-shape.

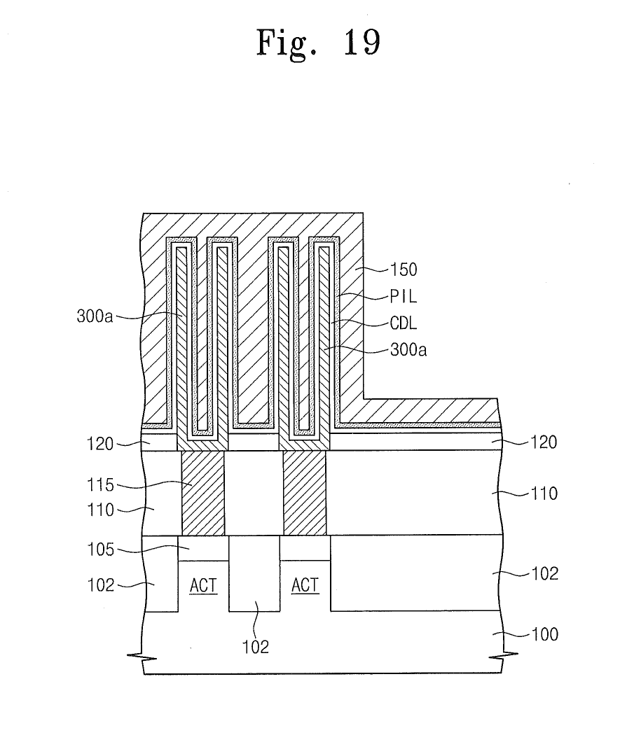

Referring to FIG. 19, the filling patterns 305a and the mold layer 125 may be removed to expose surfaces of the lower electrodes 300a. The exposed surface of the lower electrode 300a includes an inner surface and an outer surface of the lower electrode 300a.

Subsequently, the capacitive dielectric layer CDL described with reference to FIGS. 1 and 2 is formed on the substrate 100. The capacitive dielectric layer CDL may be conformally formed on the exposed surfaces of the lower electrodes 300a. In other words, the capacitive dielectric layer CDL may cover the inner surfaces and outer surfaces of the lower electrodes 300a. Next, the protection insulating layer PIL described with reference to FIGS. 1 and 2 is formed on the capacitive dielectric layer CDL. The protection insulating layer PIL may conformally cover the surfaces of the lower electrodes 300a. In other words, the protection insulating layer PIL may cover the inner surfaces and the outer surfaces of the lower electrodes 300a. Next, an upper electrode layer 150 may be formed on the protection insulating layer PIL. The upper electrode layer 150 may covers the surfaces of the lower electrodes 300a. The upper electrode layer 150 may be patterned to form the upper electrode 150a of FIG. 6.

The semiconductor devices in the aforementioned embodiments may be encapsulated using various packaging techniques. For example, the semiconductor devices according to the aforementioned embodiments may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

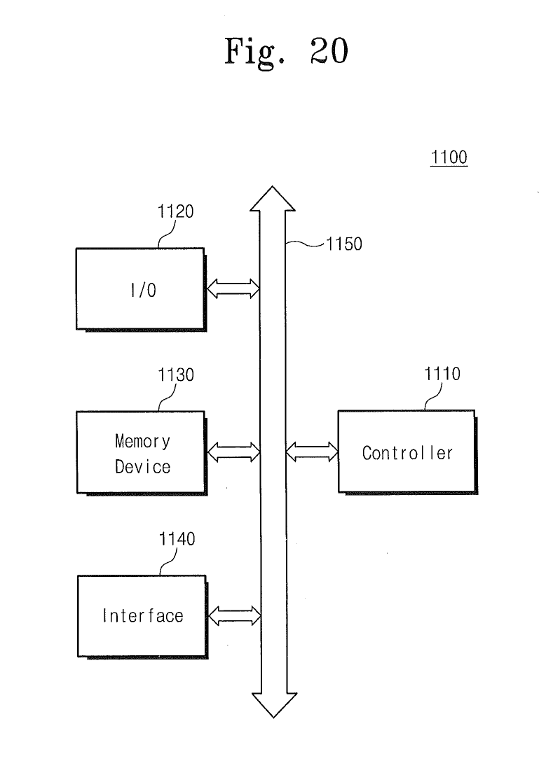

FIG. 20 is a schematic block diagram illustrating an example of electronic systems including semiconductor devices according to embodiments of the inventive concepts.

Referring to FIG. 20, an electronic system 1100 according to an embodiment of the inventive concept may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include at least one of a microprocessor, a digital signal processor, a microcontroller, or other logic devices having a similar function to any one thereof. If the semiconductor devices in the aforementioned embodiments are realized as logic devices, the controller 1110 may include at least one of the semiconductor devices in the aforementioned embodiments. The I/O unit 1120 may include a keypad, a keyboard and/or a display unit. The memory device 1130 may store data and/or commands. If the semiconductor devices according to the embodiments described above are realized as semiconductor memory devices, the memory device 1130 may include at least one of the semiconductor devices according to the embodiments described above. Additionally, the memory device 1130 may further include at least one of non-volatile memory devices (e.g. a flash memory device, a phase change memory device, a magnetic memory device, and/or a resistive memory device, etc). The interface unit 1140 may transmit electrical data to a communication network or may receive electrical data from a communication network. The interface unit 1140 may operate by wireless or cable. For example, the interface unit 1140 may include an antenna for wireless communication or a transceiver for cable communication. Although not shown in the drawings, the electronic system 1100 may further include a cache memory device for improving an operation of the controller 1110. If the semiconductor devices in the aforementioned embodiments are realized as fast DRAM devices, the cache memory device may include at least one of the semiconductor devices according to the aforementioned embodiments.

The electronic system 1100 may be applied to a personal digital assistant (PDA), a portable computer, a web tablet, a wireless phone, a mobile phone, a digital music player, a memory card or other electronic products. The other electronic products may receive or transmit information data by wireless.

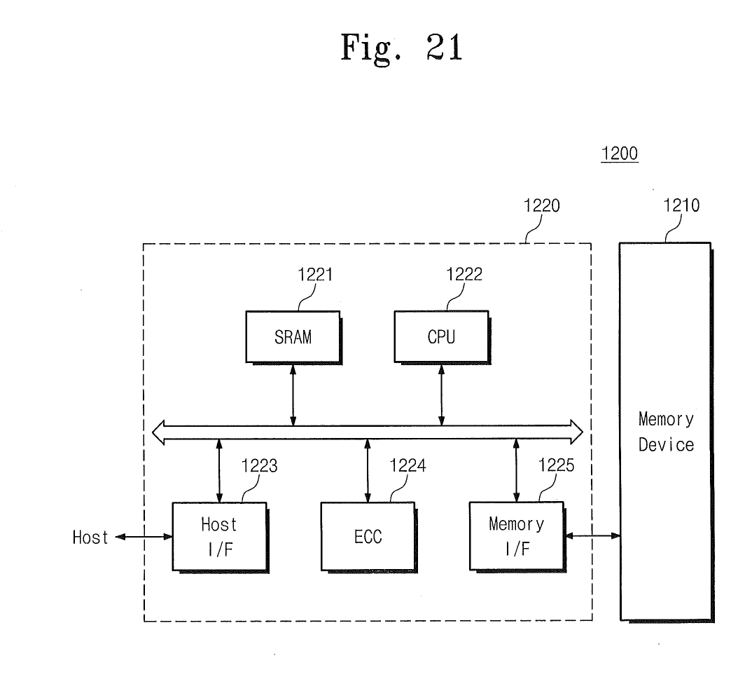

FIG. 21 is a schematic block diagram illustrating an example of memory cards including semiconductor devices according to embodiments of the inventive concepts.

Referring to FIG. 21, a memory card 1200 according to an embodiment of the inventive concept may include a memory device 1210. The memory device 1210 may include at least one of non-volatile memory devices (e.g. a flash memory device, a phase change memory device, a magnetic memory device, and/or a resistive memory device, etc). Additionally, if the semiconductor devices according to the aforementioned embodiments are realized as semiconductor memory devices, the memory device 1210 may include at least one of the semiconductor devices according to the embodiments mentioned above. The memory card 1200 may include a memory controller 1220 that controls data communication between a host and the memory device 1210.

The memory controller 1220 may include a central processing unit (CPU) 1222 that controls overall operations of the memory card 1200. If the semiconductor devices in the embodiments described above are realized as logic devices, the CPU 1222 may include at least one of the semiconductor devices in the embodiments described above. In addition, the memory controller 1220 may include an SRAM device 1221 used as an operation memory of the CPU 1222. Moreover, the memory controller 1220 may further include a host interface unit 1223 and a memory interface unit 1225. The host interface unit 1223 may be configured to include a data communication protocol between the memory card 1200 and the host. The memory interface unit 1225 may connect the memory controller 1220 to the memory device 1210. The memory controller 1220 may further include an error check and correction (ECC) block 1224. The ECC block 1224 may detect and correct errors of data which are read out from the memory device 1210. Even though not shown in the drawings, the memory card 1200 may further include a read only memory (ROM) device that stores code data to interface with the host. The memory card 1200 may be used as a portable data storage card. Alternatively, the memory card 1200 may realized as solid state disks (SSD) which are used as hard disks of computer systems.

According to embodiments of the inventive concepts, the protection insulating layer including the tantalum oxide and the barrier oxide is disposed on the dielectric layer including the titanium oxide. The protection insulating layer including the tantalum oxide has the low reactivity and the excellent incubation characteristic. Thus, the protection insulating layer protects the dielectric layer from the process gas of the subsequent process performed after the formation of the protection insulating layer, and the upper electrode may be formed to have the dense structure by the excellent incubation characteristic of the protection insulating layer. Additionally, the leakage current characteristic of the protection insulating layer may be more improved by the barrier oxide. As a result, the semiconductor device having the excellent reliability and the high integration degree may be realized.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

1. A semiconductor device comprising:
a lower electrode including at least one of a noble metal and a conductive noble metal oxide;
a dielectric layer disposed on the lower electrode, the dielectric layer including titanium oxide;
a protection insulating layer disposed on the dielectric layer, the protection insulating layer including tantalum oxide and a barrier oxide; and
an upper electrode disposed on the protection insulating layer.

2. The semiconductor device of claim 1, wherein the barrier oxide has an energy band gap greater than an energy band gap of the tantalum oxide.

3. The semiconductor device of claim 2, wherein the barrier oxide of the protection insulating layer includes a specific element and oxygen,
wherein the specific element includes at least one of aluminum, zirconium, and hafnium, and
wherein a concentration of the specific element of the barrier oxide is in a range of about 0.01 at % to about 50 at % in the protection insulating layer.

4. The semiconductor device of claim 2, wherein the barrier oxide includes at least one of aluminum oxide, zirconium oxide, and hafnium oxide.

5. The semiconductor device of claim 1, wherein a thickness of the protection insulating layer is in a range of about 1 Å to about 15 Å.

6. The semiconductor device of claim 1, wherein the protection insulating layer is in an amorphous state.

7. The semiconductor device of claim 1, wherein each of the lower electrode and the dielectric layer has a crystalline structure.

8. The semiconductor device of claim 1, wherein the dielectric layer further includes an additive oxide, and
wherein the additive oxide has an energy band gap greater than an energy band gap of the titanium oxide.

9. The semiconductor device of claim 8, wherein the additive oxide includes at least one of aluminum oxide, zirconium oxide, and hafnium oxide.

10. The semiconductor device of claim 8, wherein the additive oxide includes an additive element and oxygen,
wherein the additive element includes at least one of aluminum, zirconium, and hafnium, and
wherein a concentration of the additive element of the additive oxide is in a range of about 0.01 at % to about 30 at % in the dielectric layer.

11. The semiconductor device of claim 1, wherein the upper electrode includes at least one of a noble metal and a conductive noble metal oxide.

12. The semiconductor device of claim 11, wherein the upper electrode has a crystalline structure.

13. The semiconductor device of claim 1, wherein the capacitor includes a plurality of capacitors and the plurality of capacitors include a plurality of lower electrodes,
the semiconductor device, further comprising:
a supporting pattern disposed between the lower electrodes,
wherein the dielectric layer, the protection insulating layer and the upper electrode cover surfaces of the plurality of lower electrodes and top and bottom surfaces of the supporting pattern.

14. A semiconductor device comprising:
a lower electrode including at least one of ruthenium (Ru), ruthenium oxide (RuO₂), iridium (Ir), and iridium oxide (IrO₂);
a dielectric layer on the lower electrode, the dielectric layer including titanium oxide;
a protection insulating layer on the dielectric layer, the protection insulating layer including tantalum oxide and a barrier oxide; and
an upper electrode disposed on the protection insulating layer.

15. The semiconductor device of claim 14, wherein the barrier oxide has an energy band gap greater than an energy band gap of the tantalum oxide.

16. The semiconductor device of claim 15, wherein the barrier oxide comprises a metal element including at least one of aluminum, zirconium, and hafnium, and
wherein a concentration of the metal element of the barrier oxide is in a range of about 0.01 at % to about 50 at % in the protection insulating layer.

17. The semiconductor device of claim 14, wherein the protection insulating layer is in an amorphous state.

18. The semiconductor device of claim 14, wherein each of the lower electrode and the dielectric layer has a crystalline structure.

19. The semiconductor device of claim 14, wherein the dielectric layer further includes an additive oxide having an energy band gap greater than an energy band gap of the titanium oxide.

20. The semiconductor device of claim 19, wherein the additive oxide comprises at least one of aluminum oxide, zirconium oxide, and hafnium oxide.

21.-27. (canceled)
